(19) United States
(12) Patent Application Publication
(10) Pub. No.: US 2017/0137965 A1
(43) Pub. Date: May 18, 2017

(54) GALLIUM OXIDE SUBSTRATE

(71) Applicants: TAMURA CORPORATION, Tokyo (JP); KOHA CO., LTD., Tokyo (JP)

(72) Inventors: Kimiyoshi KOSHI, Tokyo (JP); Shinya WATANABE, Tokyo (JP); Yu YAMAOKA, Tokyo (JP); Makoto WATANABE, Tokyo (JP)

(73) Assignees: TAMURA CORPORATION, Tokyo (JP); KOHA CO., LTD., Tokyo (JP)

(21) Appl. No.: 15/323,202

(22) PCT Filed: Jul. 1, 2015
(86) PCT No.: PCT/JP2015/069015

§ 371 Date: Dec. 30, 2016

(30) Foreign Application Priority Data
Jul. 2, 2014 (JP) 2014-137223

(51) Int. Cl. C30B 29/16; C30B 15/34

(52) U.S. Cl. CPC C30B 29/16; C30B 15/34

(57) ABSTRACT

Provided is a gallium oxide substrate which has less linear pits. Obtained is a gallium oxide substrate wherein the average density of linear pits in a single crystal surface is 1,000 pits/cm2 or less.

### TECHNICAL FIELD

The invention relates to a gallium oxide substrate.

### BACKGROUND ART

One of crystal growth methods used for producing a gallium oxide single crystal is the EFG (Edge-defined Film-fed Growth) method (see, e.g., PTL 1).

When the gallium oxide single crystal is produced by using the EFG method described in PTL 1, the gallium oxide single crystal is grown from gallium oxide melt.

### CITATION LIST

### Patent Literature

[PTL 1]

JP-A-2013-237591

### SUMMARY OF INVENTION

### Technical Problem

In growing the gallium oxide single crystal, oxygen is supplied onto the surface of the gallium oxide melt to prevent the evaporation of the gallium oxide melt during the crystal growth. The present inventors, however, found that if oxygen is excessively supplied onto the surface of the gallium oxide melt, a lot of linear pits are occurred on the surface of the gallium oxide single crystal at the time of processing the grown gallium oxide single crystal into a substrate.

It is an object of an invention to provide a gallium oxide substrate that has a reduced number of linear pits.

### Solution to Problem

The above object will be attained by the respective inventions defined by [1] to [3] below.

[1] A gallium oxide substrate, wherein an average value of a density of linear pits is not more than 1000 pits/cm² in a surface of a single crystal.

[2] The gallium oxide substrate defined by [1], wherein an effective carrier concentration in the single crystal is in a range of 1×10¹⁷ [/cm³] to 1×10²⁰ [/cm³].

[3] The gallium oxide substrate defined by [1], wherein an effective carrier concentration in the single crystal is in a range of 2.05×10¹⁷ [/cm³] to 2.23×10¹⁹ [/cm³].

### Advantageous Effects of Invention

According to the invention, a gallium oxide substrate that has a reduced number of linear pits can be provided.

### BRIEF DESCRIPTION OF DRAWINGS

FIG. 1 is a cross sectional view showing a main part of an EFG crystal manufacturing apparatus.

FIG. 2 is a perspective view showing a state of a main part during growth of a β-Ga₂O₃-based single crystal.

FIG. 3 is an optical micrograph showing the surface state of a gallium oxide substrate polished by CMP.

FIG. 4 is an optical micrograph showing the surface state of the gallium oxide substrate etched with phosphoric acid.

FIG. 5 is a graph showing a relation between an effective carrier concentration in the β-Ga₂O₃-based single crystal and the number of linear pits on the β-Ga₂O₃-based single crystal per unit area.

### DESCRIPTION OF EMBODIMENTS

Preferred embodiments of the invention will be specifically described below in conjunction with the appended drawings.

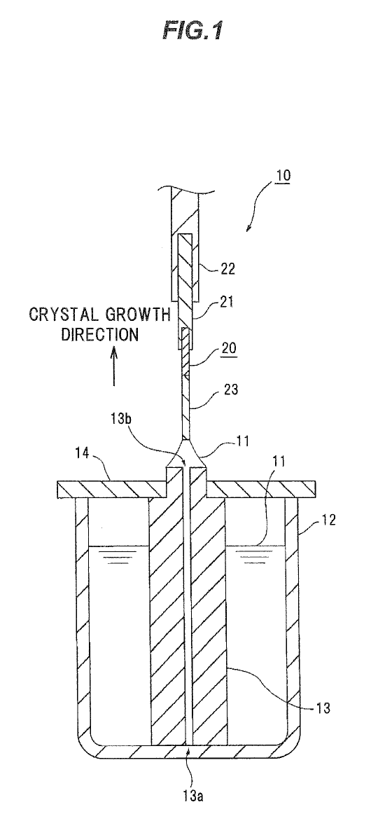

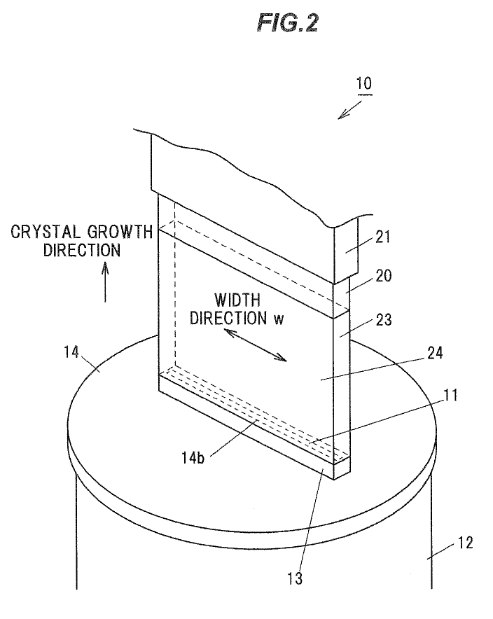

FIGS. 1 and 2 schematically shows an EFG crystal manufacturing apparatus generally denoted by the reference numeral 10.

The EFG crystal manufacturing apparatus 10 is provided with a crucible 12 containing Ga₂O₃-based melt 11 obtained by melting Ga₂O₃-based powder, a die 13 placed in the crucible 12, a lid 14 covering the upper surface of the crucible 12 except an opening 13b of a slit 13a, a seed crystal holder 21 for holding a β-Ga₂O₃-based seed crystal (hereinafter, referred as “seed crystal”) 20, and a shaft 22 vertically movably supporting the seed crystal holder 21.

The crucible 12 is formed of a heat-resistant metal material such as iridium capable of containing the Ga₂O₃-based melt 11. The die 13 has the slit 13a to draw up the Ga₂O₃-based melt 11 by capillary action. The lid 14 prevents the high-temperature Ga₂O₃-based melt 11 from evaporating from the crucible 12 and also prevents the vapor of the Ga₂O₃-based melt 11 from attaching to a portion other than the upper surface of the slit 13a.

The seed crystal 20 is moved down and is brought into contact with the Ga₂O₃-based melt 11 drawn up to the opening 13b through the slit 13a of the die 13 by capillary action, and the seed crystal 20 in contact with the Ga₂O₃-based melt 11 is pulled up, thereby growing a β-Ga₂O₃-based single crystal 23 into a plate shape. The crystal orientation of the β-Ga₂O₃-based single crystal 23 is the same as the crystal orientation of the seed crystal 20. To control the crystal orientation of the β-Ga₂O₃-based single crystal 23, for example, a plane orientation and an angle in a horizontal plane of the bottom surface of the seed crystal 20 are adjusted.

A surface 24 is a principal surface of the β-Ga₂O₃-based single crystal 23 which is parallel to a slit direction of the slit 13a. When a β-Ga₂O₃-based substrate is formed by cutting the grown β-Ga₂O₃-based single crystal 23, the plane orientation of the surface 24 of the β-Ga₂O₃-based single crystal 23 is made to coincide with the plane orientation of the principal surface of the β-Ga₂O₃-based substrate. For example, when forming a β-Ga₂O₃-based substrate of which principal surface is, e.g., a (−201) plane, the plane orientation of the surface 24 is (−201).

The seed crystal 20 and the β-Ga₂O₃-based single crystal 23 are β-Ga₂O₃ single crystals, or β-Ga₂O₃ single crystals containing an element such as Cu, Ag, Zn, Cd, Al, In, Si, Ge or Sn.

The β-Ga₂O₃-based single crystal 23 is grown using a mixed gas of oxygen O₂ and at least one type of inert gas such as nitrogen N₂, argon Ar or helium He. The atmosphere used for growth of the β-Ga₂O₃-based single crystal 23 is a mixture of nitrogen N₂ and oxygen O₂ in the present embodiment, but it is not particularly limited thereto.

Since the Ga₂O₃-based melt 11 evaporates during the growth of the β-Ga₂O₃-based single crystal 23, it is preferable that a β-Ga₂O₃ single crystal be formed under the condition of the gas with a required flow ratio of oxygen to the Ga₂O₃-based melt 11. The upper limit of the flow ratio of oxygen O₂ to nitrogen N₂ is controlled to not more than 2% in the present embodiment, but it is not particularly limited thereto.

A gallium oxide substrate is cut out from the β-Ga₂O₃-based single crystal 23 having an average linear pit density of not more than 1000 pits/cm².

Pits are crystal defects which appear as recesses on a crystal surface. The linear pits mentioned above are linear pits having a length of about several μm to several hundred μm and extending in a [010] direction. The length, width, depth and shape, etc., thereof are not specifically limited but point pits are not regarded as the linear pits.

Based on the findings by the present inventors, the yield of devices can be increased when gallium oxide substrates having an average linear pit density of not more than 1000 pits/cm² are used to manufacture the devices. Thus, not more than 1000 pits/cm² of the average linear pit density can be an indicator for proving a high-quality gallium oxide substrate.

A linear pit density of the gallium oxide substrate which is cut out from the β-Ga₂O₃-based single crystal 23 is evaluated by, e.g., the following method.

To evaluate the linear pit density, a thin plate-shaped gallium oxide substrate is firstly cut out from the β-Ga₂O₃-based single crystal 23. Next, a principal surface of the thin plate-shaped gallium oxide substrate is polished.

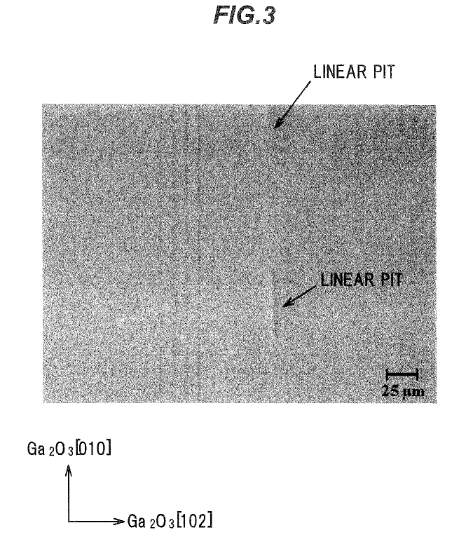

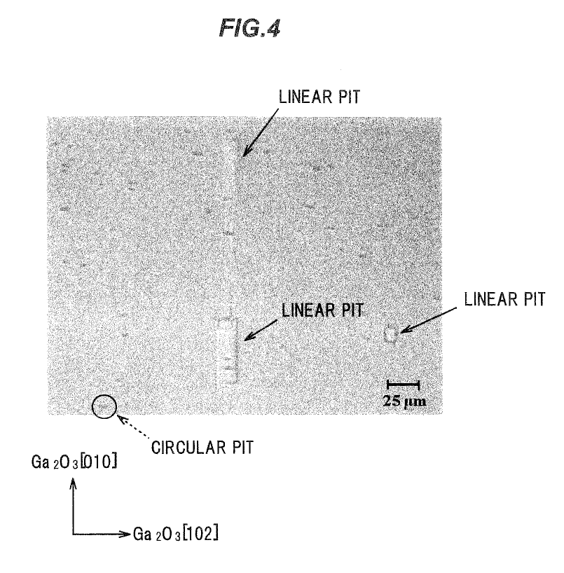

FIG. 3 is an optical micrograph showing the surface state of a gallium oxide substrate polished by CMP (chemical mechanical planarization). FIG. 4 is an optical micrograph showing the surface state of the gallium oxide substrate etched with phosphoric acid. In general, the substrate manufacturing process is completed with CMP. However, in the present embodiment, phosphoric acid etching is also performed for the purpose of evaluation to allow linear pits to be easily observed, and the linear pit density is checked by counting the number of pits per unit area.

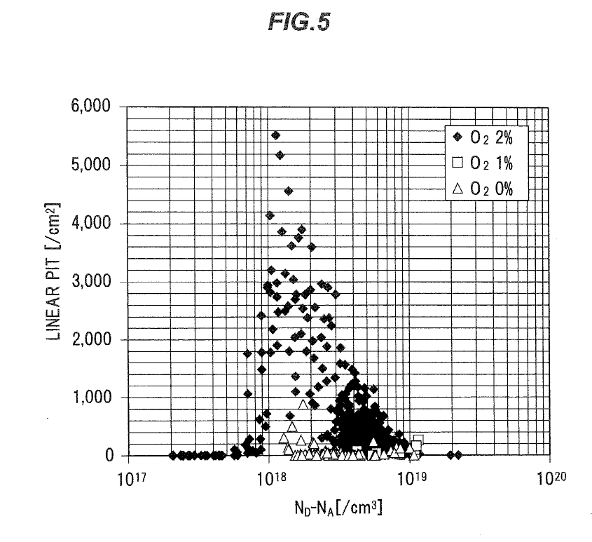

FIG. 5 is a graph showing a relation between a difference between a donor concentration N_{D} and an acceptor concentration NA (an effective carrier concentration N_{D}-N_{A}) in the β-Ga₂O₃-based single crystal 23 per unit cubic centimeter and the number of linear pits on the β-Ga₂O₃-based single crystal 23 per unit area. The effective carrier concentration was evaluated by C-V measurement. The measurement range of the effective carrier concentration is from 1×10¹⁷ to 1×10²⁰ [/cm³].

In FIG. 5, filled diamonds indicate the measured values when the flow ratio of oxygen O₂ to nitrogen N₂ is 2%, open squares indicate the measured values when the flow ratio of oxygen O₂ to nitrogen N₂ is 1%, and open triangles indicate the measured values when the flow ratio of oxygen O₂ to nitrogen N₂ is 0%.

When the flow ratio of oxygen O₂ to nitrogen N₂ supplied during growth of the β-Ga₂O₃-based single crystal is reduced from 2% to not more than 1%, the average density of linear pits occurred on the surface of the gallium oxide substrate cut out from the β-Ga₂O₃-based single crystal 23 can be reduced to not more than 1000 pits/cm².

When the flow ratio of oxygen O₂ to nitrogen N₂ is 2%, the average density of linear pits occurred on the surface of the gallium oxide substrate varies depending on the level of the effective carrier concentration N_{D}-N_{A}, as obvious from FIG. 5. On the other hand, when the flow ratio of oxygen O₂ to nitrogen N₂ is not more than 1%, the linear pits can be reduced to not more than 1000 pits/cm² regardless of the level of the effective carrier concentration N_{D}-N_{A}.

Based on FIG. 5, a lower limit in the measurement range of the effective carrier concentration N_{D}-N_{A} is 2.05×10¹⁷ [/cm³] when the flow ratio of oxygen O₂ to nitrogen N₂ is 2%.

When the flow ratio of oxygen O₂ to nitrogen N₂ is 2%, the linear pit density of the β-Ga₂O₃-based single crystal 23 is zero even if the effective carrier concentration N_{D}-N_{A} is reduced to the range of 2.05×10¹⁷ to 5.96×10¹⁷ [/cm³], and it is derived therefrom that the linear pit density is zero even at the effective carrier concentration N_{D}-N_{A} of not more than 2.05×10¹⁷ [/cm³]. Thus, it is derived that the linear pit density is zero even when the effective carrier concentration is reduced to about 1×10¹⁷ [/cm³] which is the lower limit of the evaluation range.

On the other hand, an upper limit in the measurement range of the effective carrier concentration N_{D}-N_{A} is 2.23×10¹⁹ [/cm³] when the flow ratio of oxygen O₂ to nitrogen N₂ is 2%, as shown in FIG. 5.

When the flow ratio of oxygen O₂ to nitrogen N₂ is 2%, the linear pit density of the β-Ga₂O₃-based single crystal 23 is zero even if the effective carrier concentration N_{D}-N_{A} is increased to the range of 1.17×10¹⁹ to 2.23×10¹⁹ [/cm³], and it is derived therefrom that the linear pit density is zero even at the effective carrier concentration N_{D}-N_{A} of not less than 2.23×10¹⁹ [/cm³]. Thus, it is derived that the linear pit density is zero even when the effective carrier concentration is increased to about 1×10²⁰ [/cm³] which is the upper limit of the evaluation range.

When the flow ratio of oxygen O₂ to nitrogen N₂ is 1%, a lower limit in the measurement range of the effective carrier concentration N_{D}-N_{A} is 4.2×10¹⁸ [/cm³] and an upper limit in the measurement range of the effective carrier concentration N_{D}-N_{A} is 1.15×10¹⁹ [/cm³].

Thus, if the effective carrier concentration N_{D}-N_{A} is in the range of 4.2×10¹⁸ to 1.15×10¹⁹ [/cm³], the average density of linear pits on the β-Ga₂O₃-based single crystal 23 can be reduced to not more than 1000 pits/cm² by controlling the oxygen flow rate to 1%.

When the flow ratio of oxygen O₂ to nitrogen N₂ is 0%, a lower limit in the measurement range of the effective carrier concentration N_{D}-N_{A} is 1.28×10¹⁸ [/cm³] and an upper limit in the measurement range of the effective carrier concentration N_{D}-N_{A} is 1.07×10¹⁹ [/cm³].

Thus, if the effective carrier concentration N_{D}-N_{A} is in the range of 1.28×10¹⁸ to 1.07×10¹⁹ [/cm³], the average density of linear pits on the β-Ga₂O₃-based single crystal 23 can be reduced to not more than 1000 pits/cm² by controlling the oxygen flow rate to 0%.

### Effects of the Embodiment

In the present embodiment, a gallium oxide substrate having an average linear pit density of not more than 1000 pits/cm² can be obtained by controlling the amount of oxygen in the atmosphere gas used during growth of the β-Ga₂O₃-based single crystal 23.

By using such gallium oxide substrate as a growth substrate, it is possible to epitaxially grow a high-quality crystal film with low linear pit density.

As a result, it is possible to increase the yield of LED device or power device, etc., formed using the gallium oxide substrate and a crystal film thereon.

Although the typical embodiment, modification and illustrated example of the invention have been described, the invention according to claims is not intended to be limited to the embodiment, modification and illustrated example, as obvious from the above description. Therefore, it should be noted that all combinations of the features described in the embodiment, modification and illustrated example are not necessary to solve the problem of the invention.

### Industrial Applicability

A gallium oxide substrate which has a reduced number of linear pits is provided.

### Reference Signs List

10 EFG CRYSTAL MANUFACTURING APPARATUS
11 Ga₂O₃-BASED MELT
12 CRUCIBLE
13 DIE
13a SLIT
13b OPENING
14 LID
20 β-Ga₂O₃-BASED SEED CRYSTAL
21 SEED CRYSTAL HOLDER
22 SHAFT
23 β-Ga₂O₃-BASED SINGLE CRYSTAL

1. A gallium oxide substrate, wherein an average value of a density of linear pits is not more than 1000 pits/cm² in a surface of a single crystal.

2. The gallium oxide substrate according to claim 1, wherein an effective carrier concentration in the single crystal is in a range of 1×10¹⁷ [/cm³] to 1×10²° [/cm³].

3. The gallium oxide substrate according to claim 1, wherein an effective carrier concentration in the single crystal is in a range of 2.05×10¹⁷ [/cm³] to 2.23×10¹⁹ [/cm³].
